(19) United States
(12) Patent Application Publication
(10) Pub. No.: US 2023/0284379 A1
(43) Pub. Date: Sep. 7, 2023

(54) POWER CONVERSION DEVICE

(71) Applicant: Mitsubishi Electric Corporation, Tokyo (JP)

(72) Inventor: Yusuke TSUBAKI, Tokyo (JP)

(73) Assignee: Mitsubishi Electric Corporation, Tokyo (JP)

(21) Appl. No.: 18/096,708

(22) Filed: Jan. 13, 2023

(30) Foreign Application Priority Data
Mar. 3, 2022 (JP) 2022-032219

(51) Int. Cl. H05K 1/02; H02M 1/00; H02M 3/00; H02M 3/335; H05K 1/18

(52) U.S. Cl. CPC H05K 1/0296; H02M 1/0009; H02M 3/003; H02M 3/33573; H05K 1/181; H05K 2201/10151

(57) ABSTRACT

A power conversion device includes: a power conversion circuit having semiconductor switching elements; a current transformer connected to an input power supply and the power conversion circuit; a printed circuit board on which the current transformer is disposed; a board pattern which is a conductor pattern formed on an upper surface of the printed circuit board; and a connecting wire formed of a conductor, in which at least one of a wire connecting the current transformer and the input power supply and a wire connecting the current transformer and the power conversion circuit includes the board pattern and the connecting wire connected to an upper surface of the board pattern.

### TECHNICAL FIELD

The present disclosure relates to a power conversion device.

### BACKGROUND ART

Multiple power conversion devices are mounted in an electric vehicle, such as an electric car or a hybrid car, in which a motor is used as a driving source. Such power conversion devices are, for example, a battery charger that converts an alternating voltage from a commercial alternating current power supply into a direct current (DC) voltage and charges a high voltage battery with the DC voltage, a DC to DC converter that converts a DC voltage of the high voltage battery into a voltage (e.g., 12V) of a battery used for auxiliary devices, and an inverter that converts a direct current power from the battery into an alternating current power to be supplied to a motor.

For example, Patent Literature 1 discloses a power conversion device including: a main body of the power conversion device that performs switching of input power via semiconductor switching elements, thereby generating output power; and a noise filter circuit that is provided on an input side of the main body of the power conversion device, and that reduces an outer flow of a high frequency noise to an input power supply system, the high frequency noise caused by the switching operation of the main body of the power conversion device. In the power conversion device, the noise filter circuit is mounted on a filter circuit board together with a fuse that melts in the event of failure to disconnect the main body of the power conversion device from the input power supply system.

On the filter circuit board, an across-the-line capacitor which is inserted between input power lines and constitutes a part of the noise filter circuit, a discharging resistor for this across-the-line capacitor, the fuse, and filter components which constitute the remaining portion of the noise filter circuit excluding the across-the-line capacitor are arranged in order in a direction away from an input power supply terminal connected to a power source line of the input power supply system. Further, some power conversion devices each have a current sensor for detecting a current flowing from an input power supply to a power conversion circuit. On a printed circuit board which is a filter circuit board, a fuse, the current sensor, etc. are connected to a main circuit line.

### CITATION LIST

### Patent Literature

Patent Literature 1: JP 2016-192837 A

### SUMMARY OF INVENTION

### Technical Problem

However, in the conventional power conversion device described in Patent Literature 1, because a high current is supplied to the main circuit line disposed on the printed circuit board, it is necessary to increase the wire width of the main circuit line and so on from the viewpoint of thermal feasibility. In addition, the self-generated heat of electrical components including the fuse and the current sensor is also applied to the main circuit line. In this case, a problem with this conventional technology is that in order to suppress the generation of heat in the wires, it is necessary to increase the widths of the wires. The increase in the wire width of the main circuit line and so on leads to upsizing of the power conversion device.

Further, as for a conventional technology of suppressing the increase in the wire width of a main circuit line, there is a technology of thermally connecting a printed circuit board and a part of a housing containing the printed circuit board via an insulating member by disposing the insulating member between the part of the housing and the printed circuit board. However, this technique has a necessity to ensure an insulation distance between the printed circuit board on which the main circuit line is disposed, and the part of the housing. In this case, because a region where any component cannot be arranged is formed on the printed circuit board, the power conversion device is upsized.

The present disclosure is made to solve the above-mentioned problem, and it is therefore an object of the present disclosure to obtain a power conversion device that can suppress an increase in the widths of wires connecting electrical components inside of the device.

### Solution to Problem

According to the present disclosure, there is provided a power conversion device including: a power conversion circuit having multiple semiconductor switching elements; an electrical component connected to an input power supply and the power conversion circuit; a printed circuit board for which the electrical component is provided; a board pattern which is a conductor pattern formed on an upper surface of the printed circuit board; and a connecting wire formed of a conductor, in which at least one of a wire connecting the electrical component and the input power supply and a wire connecting the electrical component and the power conversion circuit includes the board pattern and the connecting wire connected to an upper surface of the board pattern.

### Advantageous Effects of Invention

According to the present disclosure, at least one of the wire connecting the electrical component and the input power supply and the wire connecting the electrical component and the power conversion circuit includes the board pattern and the connecting wire connected to the upper surface of the board pattern. The connecting wire functions as a heat generation suppression member for the board pattern, and the generation of heat in the wire is suppressed without having to increase the wire width of the wire connecting the electrical component. As a result, the power conversion device according to the present disclosure makes it possible to suppress the increase in the wire width of the wire connecting the electrical component inside the device.

### BRIEF DESCRIPTION OF DRAWINGS

FIG. 1 is a circuit diagram showing an outline of the configuration of a power conversion device according to Embodiment 1;

FIG. 2 is a top view showing the power conversion device according to Embodiment 1;

FIG. 3 is a partial cross-sectional arrow view showing a cross section of the power conversion device according to Embodiment 1, taken along the A-A line of FIG. 2;

FIG. 4 is a top view showing a power conversion device according to Embodiment 2;

FIG. 5 is a partial cross-sectional arrow view showing a cross section of the power conversion device according to Embodiment 2, taken along the B-B line of FIG. 4;

FIG. 6 is a top view showing a power conversion device according to Embodiment 3; and

FIG. 7 is a partial cross-sectional arrow view showing a cross section of the power conversion device according to Embodiment 3, taken along the C-C line of FIG. 6.

### DESCRIPTION OF EMBODIMENTS

### Embodiment 1

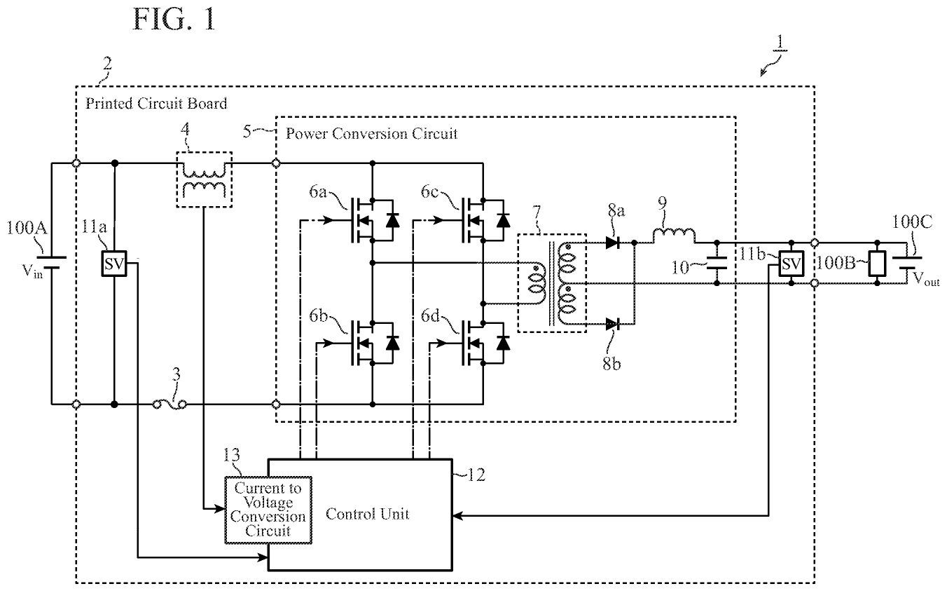

FIG. 1 is a circuit diagram showing an outline of the configuration of a power conversion device 1 according to Embodiment 1. As shown in FIG. 1, the power conversion device 1 is disposed on a printed circuit board 2. In practical cases, the printed circuit board 2 on which the power conversion device 1 is disposed is contained in a housing not shown in FIG. 1. The power conversion device 1 is, for example, a DC to DC converter. The power conversion device 1, which is a DC to DC converter, is configured in such a way as to include a fuse 3, a current transformer 4, a power conversion circuit 5, an input voltage detection circuit 11a, an output voltage detection circuit 11b, a control unit 12 and a current to voltage conversion circuit 13 between an input power supply 100A, and an external load 100B and an output power supply 100C.

The fuse 3 is disposed between the input power supply 100A and the power conversion circuit 5, and, when the power conversion device 1 breaks down, melts to cut off the connection between the input power supply 100A and the power conversion circuit 5. The current transformer 4 is disposed between the input power supply 100A and the power conversion circuit 5, and functions as an insulated type current sensor that detects an input current from the input power supply 100A. The input current detected by the current transformer 4 is outputted to the current to voltage conversion circuit 13. The current to voltage conversion circuit 13 converts the input current into a voltage, and outputs the voltage to the control unit 12.

The power conversion circuit 5 includes semiconductor switching elements 6a to 6d, a transformer 7, semiconductor elements 8a and 8b, a smoothing reactor 9 and a smoothing capacitor 10. The four semiconductor switching elements 6a to 6d constitute an inverter circuit. As for the semiconductor switching elements 6a to 6d, for example, metal-oxide-semiconductor field-effect transistors (MOSFETs) are used. To a subsequent stage of the input power supply 100A, the semiconductor switching elements 6a to 6d are connected. The input power supply 100A is a high voltage battery, and generates a DC voltage Vᵢₙ.

Further, the input voltage detection circuit 11a is connected in parallel with the input power supply 100A. The input voltage detection circuit 11a detects the DC voltage Vᵢₙ generated by the input power supply 100A. The DC voltage Vᵢₙ detected by the input voltage detection circuit 11a is outputted to the control unit 12. The control unit 12 performs on-off driving of the semiconductor switching elements 6a to 6d, by outputting control signals to the semiconductor switching elements 6a to 6d via control lines shown by alternate long and short dash lines in FIG. 1.

To a point of connection between a source terminal of the semiconductor switching element 6a and a drain terminal of the semiconductor switching element 6b, one end of a primary winding of the transformer 7 is connected. In addition, to a point of connection between a source terminal of the semiconductor switching element 6c and a drain terminal of the semiconductor switching element 6d is connected the other end of the primary winding of the transformer 7. Further, to a secondary winding of the transformer 7 are connected the semiconductor elements 8a and 8b. The semiconductor elements 8a and 8b are elements which constitute a rectifier circuit, and, for example, diodes for rectification are used as the semiconductor elements 8a and 8b.

The smoothing reactor 9 smooths the DC voltage rectified by the semiconductor elements 8a and 8b. The smoothing capacitor 10 smooths the voltage waveform of a current flowing through the smoothing reactor 9, thereby outputting the smoothed voltage as an output voltage Vₒᵤₜ to a subsequent stage. The output voltage Vₒᵤₜ is consumed by the external load 100B or used for charging of the output power supply 100C. To the stage subsequent to the smoothing capacitor 10, the output voltage detection circuit 11b is connected in parallel with the external load 100B. The output voltage detection circuit 11b detects the smoothed output voltage Vₒᵤₜ and outputs the smoothed output voltage to the control unit 12.

The control unit 12 acquires, via a signal line, voltage or current information which is outputted by the current transformer 4, the input voltage detection circuit 11a or the output voltage detection circuit 11b, and performs on-off driving of the semiconductor switching elements 6a to 6d on the basis of the voltage or current information. In a case where the DC to DC converter shown in FIG. 1 needs to reduce a noise occurring from the power conversion circuit 5, an across-the-line capacitor, a line-bypass capacitor, a choking coil or the like is connected between the input power supply 100A and the semiconductor switching elements 6a to 6d or between the smoothing capacitor 10 and the external load 100B.

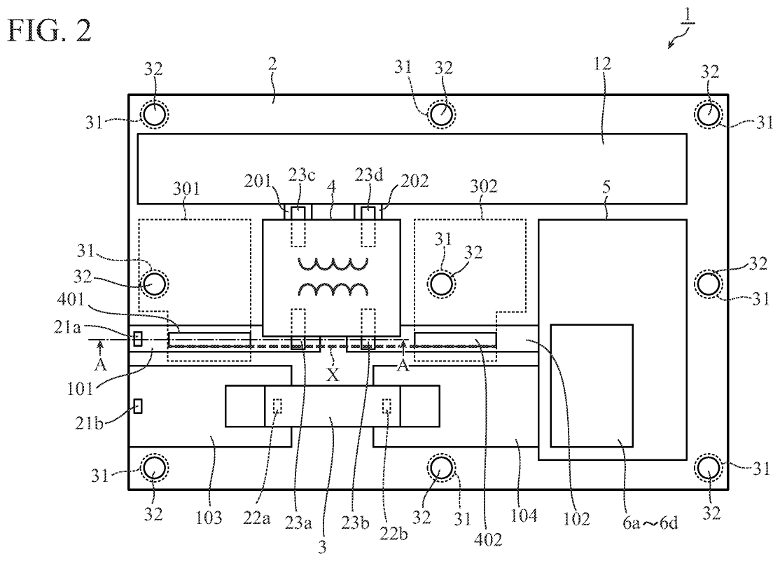

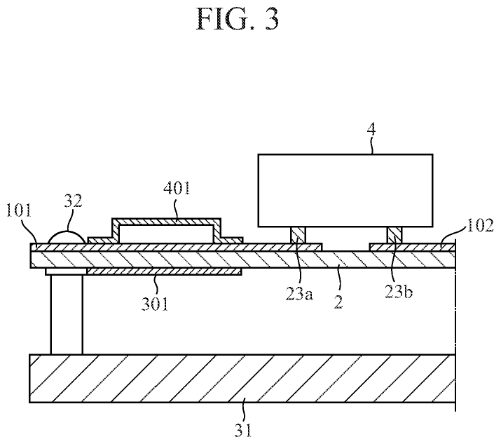

FIG. 2 is a top view showing the power conversion device 1, and shows a concrete configuration of the power conversion device 1 disposed on the printed circuit board 2. In FIG. 2, the printed circuit board 2 is a two-layer board. Although the printed circuit board 2 is a two-layer board which makes it possible to mount components on upper and lower surfaces thereof, this embodiment is not limited to this example and the printed circuit board 2 may be a multilayer board having three or more layers. FIG. 3 is a partial cross-sectional arrow view showing a cross section of the power conversion device 1, taken along the A-A line of FIG. 2. In FIG. 3, the control unit 12 is not shown for the sake of simplicity of illustration.

On the upper surface of the printed circuit board 2, an input power supply terminal 21a on a positive side and an input power supply terminal 21b on a negative side are arranged, and the fuse 3, the current transformer 4, the power conversion circuit 5 and the control unit 12 are mounted. The input power supply terminals 21a and 21b are connected to the input power supply 100A shown in FIG. 1. The power conversion circuit 5 has the semiconductor switching elements 6a to 6d. As shown in FIG. 3, the printed circuit board 2 is contained inside the housing 31, and is fastened to the housing 31 using screws 32.

Although in FIG. 2 all the components including the semiconductor switching elements 6a to 6d in the power conversion circuit 5 are mounted on the surfaces of the printed circuit board 2, this embodiment is not limited to this configuration. For example, the power conversion device 1 may have a configuration in which only input terminals of the power conversion circuit 5 are connected on the printed circuit board 2. Concretely, the power conversion device 1 may have a configuration in which components such as the transformer 7 and the smoothing reactor 9 included in the power conversion circuit 5, in addition to the multiple semiconductor switching elements 6a to 6d, are arranged in the housing 31 without being mounted on a surface of the printed circuit board 2, and each of the components is connected using a bus bar.

Board patterns 101 to 104, 201, 202, 301 and 302 are conductor patterns formed on the surfaces of the printed circuit board 2. The board patterns 101 to 104, 201 and 202 are formed on the upper surface of the printed circuit board 2, and the board patterns 301 and 302 are formed on the surface (lower surface) opposite to the upper surface of the printed circuit board 2 on which the board pattern 101 is formed, as shown by broken lines in FIG. 2.

In a case where the printed circuit board 2 is a multilayer board and the board patterns 101 to 104, 201 and 202 are formed in one layer in a laminating direction of the printed circuit board 2, the board patterns 301 and 302 should just be formed in a layer above or under the layer in which the board patterns 101 to 104, 201 and 202 are formed. More specifically, the board patterns 301 and 302 are formed either on a different surface or in a different layer of the printed circuit board 2, in a board thickness direction of the board, from a surface of the printed circuit board 2 on which the board pattern 101 is formed.

The board pattern 101 is a first board pattern having a band shape, and a first end of the board pattern 101 is disposed in an end portion of the printed circuit board 2, for example. At the part of the board pattern 101 disposed in the end portion of the printed circuit board 2, the input power supply terminal 21a on the positive side is disposed. To the input power supply terminal 21a, a positive input voltage from the input power supply 100A shown in FIG. 1 is applied.

The board pattern 301 is a second board pattern formed on the lower surface of the printed circuit board 2. For example, the board pattern 301 is disposed below a connecting wire 401 when viewed from the upper surface of the printed circuit board 2, as shown in FIG. 2.

In the case where the printed circuit board 2 is a multilayer board, the board pattern 301 is disposed, in the layer in which the board pattern 301 is formed, at a position where the board pattern 301 overlaps the connecting wire 401 when viewed from the upper surface of the printed circuit board 2.

The board pattern 102 is a fourth board pattern having a band shape, and is disposed on the upper surface of the printed circuit board 2 with a spacing from the board pattern 101, for example. A first end of the board pattern 102, the first end being opposite to a second end of the board pattern 102 and the second end facing the board pattern 101, is connected to the power conversion circuit 5.

The board pattern 302 is a fifth board pattern formed on the lower surface of the printed circuit board 2. For example, the board pattern 302 is disposed below a connecting wire 402 when viewed from the upper surface of the printed circuit board 2, as shown in FIG. 2.

Further, in the case where the printed circuit board 2 is a multilayer board, the board pattern 302 is disposed, in the layer in which the board pattern 302 is formed, at a position where the board pattern 302 overlaps the connecting wire 402 when viewed from the upper surface of the printed circuit board 2, like the board pattern 301.

The board pattern 103 has a band shape wider than the board pattern 101, and a first end of the board pattern 103 is disposed in the end portion of the printed circuit board 2. At the part of the board pattern 103 disposed in the end portion of the printed circuit board 2, the input power supply terminal 21b on the negative side is disposed. To the input power supply terminal 21b, a negative input voltage from the input power supply 100A shown in FIG. 1 is applied. The board pattern 104 has a band shape of the same width as the board pattern 103, and is disposed with a spacing from the board pattern 103. Further, a first end of the board pattern 104, the first end being opposite to a second end of the board pattern 104 and the second end facing the board pattern 103, is connected to the power conversion circuit 5. The shapes of the board patterns 101, 102, 103 and 104 are not limited to band shapes, and may be other shapes.

The fuse 3 is an electrical component having an input terminal 22a and an output terminal 22b. The input terminal 22a of the fuse 3 is connected to a second end of the board pattern 103, the second end being opposite to the first end of the board pattern 103 at which the input power supply terminal 21b is disposed. The output terminal 22b of the fuse 3 is connected to the second end of the board pattern 104, the second end facing the board pattern 103.

The current transformer 4 is an electrical component having an input terminal 23a and an output terminal 23b on a primary side thereof, and having an input terminal 23c and an output terminal 23d on a secondary side thereof. The input terminal 23a of the current transformer 4 is connected to a second end of the board pattern 101, the second end being opposite to the first end of the board pattern 101 at which the input power supply terminal 21a is disposed. The output terminal 23b of the current transformer 4 is connected to the second end of the board pattern 102, the second end facing the board pattern 101. Further, the current transformer 4 is also an insulated type current sensor that detects the input current from the input power supply terminal 21a.

A wire connecting the input terminal 23a of the current transformer 4 and the input power supply 100A includes the board pattern 101 and the connecting wire 401 connected to an upper surface of the board pattern 101. Further, a wire connecting the power conversion circuit 5 and the output terminal 23b of the current transformer 4 includes the board pattern 102 and the connecting wire 402 connected to an upper surface of the board pattern 102. For example, a set of the board pattern 101 and the connecting wire 401 connected to the upper surface of the board pattern 101 is a wire connecting the input power supply terminal 21a connected to the input power supply 100A and the input terminal 23a of the current transformer 4 in series, and a set of the board pattern 102 and the connecting wire 402 connected to the upper surface of the board pattern 102 is a wire connecting the output terminal 23b of the current transformer 4 and the power conversion circuit 5 in series, as shown in FIG. 2.

The connecting wires 401 and 402 connected to the board patterns 101 and 102 are arranged in parallel with an imaginary line X (shown by a thick broken line in FIG. 2) which passes through the input terminal 23a and the output terminal 23b of the current transformer 4. As a result, because the board patterns 101 and 102 whose pattern widths (wire widths) are successfully decreased using the connecting wires 401 and 402 are arranged in the vicinity of the current transformer 4, the wiring area on the upper surface of the printed circuit board 2 can be used effectively.

The board pattern 103 is a wire connecting the input power supply terminal 21b and the input terminal 22a of the fuse 3 in series, and the board pattern 104 is a wire connecting the output terminal 22b of the fuse 3 and the power conversion circuit 5 in series. The board patterns 103 and 104 are ones whose pattern widths are designed in consideration of the amounts of heat generated in the fuse 3 and the board patterns 103 and 104, and which are feasible from the thermal point of view. The board pattern 201 is a wire connecting the input terminal 23c of the current transformer 4 and the control unit 12, and the board pattern 202 is a wire connecting the output terminal 23d of the current transformer 4 and the control unit 12.

Further, the connecting wire 401 is a first connecting wire connected to the upper surface of the board pattern 101. The connecting wire 402 is a second connecting wire connected to the upper surface of the board pattern 102. For example, each of the connecting wires 401 and 402 is formed of a conductor such as copper or aluminum.

For example, although the thicknesses of the board patterns 101 and 102 are within a range from several micrometers to several tens of micrometers, each of the connecting wires 401 and 402 is formed in such a way as to have a thickness of several millimeters. By thus setting the connecting wires 401 and 402 as conductor wires which are sufficiently thicker than the board patterns 101 and 102, it is possible to enhance the effect of suppressing the generation of heat in the board patterns 101 and 102. Further, both ends of the connecting wire 401 are connected to the upper surface of the board pattern 101, and the connecting wire 401 constitutes a single wire together with the board pattern 101. Both ends of the connecting wire 402 are connected to the upper surface of the board pattern 102, and the connecting wire 402 constitutes a single wire together with the board pattern 102.

Because the connecting wires 401 and 402 serve as heat generation suppression members for the board patterns 101 and 102, it is not necessary to increase the surface areas of the board patterns 101 and 102 for the purpose of heat dissipation. Therefore, the pattern widths of the board patterns 101 and 102 can be made to be narrow compared with those of the board patterns 103 and 104 connected to the fuse 3, as shown in FIG. 2. As a result, the power conversion device 1 makes it possible to suppress the increase in the wire widths of the wires connecting the electrical components inside the device, and hence to downsize the printed circuit board 2.

Further, the both ends of the connecting wire 401 are connected to the upper surface of the board pattern 101 in a state where the portion between one end and the other end of the connecting wire 401 is spaced from a surface of the printed circuit board 2, as shown in FIG. 3. The connecting wire 402 is connected to the upper surface of the board pattern 102 in a state where a gap is formed between the portion between one end and the other end of the connecting wire 402, and the surface of the printed circuit board 2, like the connecting wire 401. For example, the connecting wire 401 is electrically connected in parallel with the board pattern 101, and the connecting wire 402 is electrically connected in parallel with the board pattern 102.

In order to provide a spacing between the portion between one end and the other end of each of the connecting wires 401 and 402, and the surface of the printed circuit board 2, it is necessary to make the wire lengths of the connecting wires 401 and 402 be long compared with those in the case where no spacing is provided. Because, as the wire lengths become long, the surface areas for heat dissipation of the connecting wires 401 and 402 also increase accordingly, the heat dissipation capability is improved. Therefore, because the connecting wires 401 and 402 are connected to the upper surfaces of the board patterns 101 and 102 in the state where a spacing is provided between the portion between one end and the other end of each of the connecting wires 401 and 402, and the surface of the printed circuit board 2, the power conversion device 1 makes it possible to enhance the effect of suppressing the generation of heat in the board patterns 101 and 102.

The control unit 12 is configured in such a way as to include surface mount components such as a chip resistor and a chip capacitor. Further, the connecting wire 401 is surface-mounted on the upper surface of the board pattern 101, as shown in FIG. 3. Similarly, the connecting wire 402 is also surface-mounted on the upper surface of the board pattern 102. Therefore, the connecting wires 401 and 402 can be mounted on the board patterns 101 and 102 through the same process as that performed on other surface mount components (for example, the components of the control unit 12) arranged on the upper surface of the printed circuit board 2.

For example, by temporarily arranging the connecting wires 401 and 402 on cream solder disposed on the upper surfaces of the board patterns 101 and 102 in the same way as other surface mount components, and causing the printed circuit board 2 on which the surface mount components are temporarily arranged to pass through a reflow furnace, the cream solder is melt and the connecting wires are mounted. As a result, in the power conversion device 1, any special process of mounting the connecting wires 401 and 402 on the board patterns 101 and 102 is unnecessary, the cost to mount components on the surfaces of the printed circuit board 2 is reduced, and a cost reduction of the power conversion device 1 can be made.

The level of the connecting wire 401 from the surface of the printed circuit board 2 is lower than that of the current transformer 4, as shown in FIG. 3. The level of the connecting wire 402 is lower than that of the current transformer 4, like that of the connecting wire 401. For example, the current transformer 4 is an electrical component having the highest level from the printed circuit board 2, out of the electrical components mounted on the upper surface of the printed circuit board 2.

As a result, even in the case where the connecting wires 401 and 402 are mounted on the board patterns 101 and 102, the size in the level direction of the printed circuit board 2 can be made to fall within a range up to the level of the current transformer 4, and a downsizing of the power conversion device 1 can be achieved.

Using FIGS. 2 and 3, the configuration in which the connecting wires 401 and 402 are provided for the board patterns 101 and 102 which are the main circuit line connected to the current transformer 4 is shown as the configuration of the power conversion device 1. However, the power conversion device 1 is not limited to this configuration. For example, the power conversion device 1 can be configured in such a way that a connecting wire is disposed on either of the board patterns 101 and 102. Because even in the power conversion device 1 configured in this way, the connecting wire functions as a heat generation suppression member and the generation of heat in the board pattern to which the connecting wire is connected is suppressed without having to increase the pattern width of the board pattern, the increase in the pattern width of the board pattern connecting electrical components mounted in the power conversion device can be suppressed.

In addition, the power conversion device 1 can be configured in such a way that on a surface of the printed circuit board 2, two connecting wires are provided for the respective board patterns 103 and 104 which are the main circuit lines connected to the fuse 3. Further, a connecting wire may be disposed on each of the upper surfaces of the board patterns 101 to 104. Because also in the power conversion device 1 configured in this way, each connecting wire functions as a heat generation suppression member and the generation of heat in the board patterns 101 to 104 is suppressed without having to increase the pattern widths of the board patterns 101 to 104, the increase in the pattern widths of the board patterns 101 to 104 connecting electrical components mounted in the power conversion device can be suppressed.

The board pattern 301 is a conductor pattern formed on the lower surface of the printed circuit board 2 and is electrically connected to the housing 31. For example, the board pattern 301 is disposed at a position where the board pattern 301 completely or partially overlaps a point of connection between the board pattern 101 and the connecting wire 401 when viewed from the upper surface of the printed circuit board 2, as shown in FIG. 2. Further, the board pattern 302 is a conductor pattern formed on the lower surface of the printed circuit board 2 and is electrically connected to the housing 31. The board pattern 302 is disposed at a position where the board pattern 302 completely or partially overlaps a point of connection between the board pattern 102 and the connecting wire 402 when viewed from the upper surface of the printed circuit board 2.

In the board patterns 101 and 102, the thermal resistances of the points of connection with the connecting wires 401 and 402 are high, and the points of connection have a large influence on the thermal feasibility. Accordingly, the board pattern 301 is disposed at a position where the board pattern 301 completely or partially overlaps the point of connection between the board pattern 101 and the connecting wire 401 when viewed from the upper surface of the printed circuit board 2, and the board pattern 302 is disposed at a position where the board pattern 302 completely or partially overlaps the point of connection between the board pattern 102 and the connecting wire 402 when viewed from the upper surface of the printed circuit board 2. As a result, a heat path through which the heat from the board patterns 101 and 102 is propagated from the above-mentioned points of connection, via the printed circuit board 2 and the board patterns 301 and 302, to the housing 31 is formed. Because the generation of heat in the board patterns 101 and 102 is suppressed through this heat path, it is possible to suppress the generation of heat in the board patterns 101 and 102 even though the pattern widths of the board patterns 101 and 102 are made to be narrow compared with the configuration not having the board patterns 301 and 302.

The printed circuit board 2 is contained inside the housing 31. As shown in FIGS. 2 and 3, the printed circuit board 2 is fastened, via the board pattern 301, to the housing 31 by a screw 32, and is fastened, via the board pattern 302, to the housing 31 by a screw 32. Because the board patterns 301 and 302 are fastened to the housing 31 by the screws 32, and hence the thermal resistance between each of the board patterns 301 and 302 and the housing 31 is reduced, it is possible to enhance the effect of suppressing the generation of heat in the board patterns 101 and 102 by conduction of the heat by way of the above-mentioned heat path.

Further, although the current transformer 4 is shown as the insulated type current sensor, the power conversion device 1 can include an insulated and hole type IC as the current sensor.

In FIGS. 2 and 3, at least one of the fuse 3 and the current transformer 4 is a surface mount component to be surface-mounted on the printed circuit board 2. Further, the connecting wires 401 and 402 are surface-mounted on the board patterns 101 and 102, as mentioned above. As a result, it is possible to mount the fuse 3, the current transformer 4 and the connecting wires 401 and 402, which are arranged on a surface of the printed circuit board 2, through a common surface mounting process, and the mounting cost of the components can be reduced.

In order to connect the board patterns 101, 102, 201 and 202 to, respectively, the input terminal 23a, the output terminal 23b, the input terminal 23c and output terminal 23d which the current transformer 4 includes, it is necessary to form these board patterns on a surface of the printed circuit board 2. Further, it is necessary to ensure an insulation distance between the primary and secondary sides of the current transformer 4. Therefore, it is impossible to widen the board patterns 101 and 102 connected to the primary terminals of the current transformer 4 toward, respectively, the board patterns 201 and 202 connected to the secondary terminals of the current transformer 4 in order to suppress the generation of heat in the board patterns 101 and 102. In this case, in conventional power conversion devices, the board patterns 101 and 102 connected to the primary terminals which the current transformer 4 has are to be widened toward the fuse 3.

In contrast with this, the power conversion device 1 provides the effects of suppressing the generation of heat in the board patterns 101 and 102 without having to increase the pattern widths of the board patterns 101 and 102, by means of the connection of the connecting wires 401 and 402 to the board patterns 101 and 102. Therefore, the power conversion device 1 makes it possible to reduce the occupation areas of the board patterns 101 and 102 on the printed circuit board 2, and can be downsized.

Further, in the case where the fuse 3 is arranged in the vicinity of the current transformer 4 on the upper surface of the printed circuit board 2, as shown in FIG. 2, it is difficult to widen the board patterns 101 and 102 toward the board patterns 201 and 202, and also it is difficult to widen the board patterns 101 and 102 toward the fuse 3. In contrast, in conventional power conversion devices, it is necessary to dispose the fuse 3 at a position sufficiently apart from the current transformer 4, and the area required to arrange the fuse 3 and the current transformer 4 on a surface of the printed circuit board 2 increases.

In contrast with this, the power conversion device 1 can suppress the generation of heat in the board patterns 101 and 102 without having to widen the board patterns 101 and 102 toward either the board patterns 201 and 202 or the fuse 3, by means of the connection of the connecting wires 401 and 402 to the board patterns 101 and 102.

Further, although the case in which one connecting wire is connected to one board pattern is shown in the above explanation, the power conversion device 1 is not limited to this example. For example, the power conversion device 1 may be configured in such a way that multiple connecting wires are connected to an upper surface of one board pattern. As a result, the generation of heat in the board pattern is suppressed even though the pattern width of the board pattern is decreased.

There is a case in which in the power conversion device 1, in order to reduce a noise occurring from the power conversion circuit 5, an across-the-line capacitor, a line-bypass capacitor or a choking coil may be disposed in the vicinity of the fuse 3 or the current transformer 4, for example. Particularly in a case where a capacitor is mounted on a surface of the printed circuit board 2, a wiring area for routing wires in the vicinity of the fuse 3 and the current transformer 4 is narrow. In contrast with this, because the power conversion device 1 makes it possible to suppress the increase in the pattern widths of the board patterns using the connecting wires, the narrow wiring area can be effectively used.

As mentioned above, the power conversion device 1 according to Embodiment 1 includes: the power conversion circuit 5 having the semiconductor switching elements 6a to 6d; the current transformer 4 connected to the input power supply 100A and the power conversion circuit 5; the printed circuit board 2 on which the current transformer 4 is disposed; the board pattern 101 which is a conductor pattern formed on the upper surface of the printed circuit board 2; and the connecting wire 401 formed of a conductor, and a wire connecting the current transformer 4 and the input power supply 100A includes the board pattern 101 and the connecting wire 401 connected to the upper surface of the board pattern 101, and a wire connecting the current transformer 4 and the power conversion circuit 5 includes the board pattern 102 and the connecting wire 402 connected to the upper surface of the board pattern 102. Because the connecting wires 401 and 402 function as heat generation suppression members for the board patterns 101 and 102, and, as a result, the generation of heat in the board patterns 101 and 102 is suppressed without having to increase the pattern widths of the board patterns 101 and 102, the power conversion device 1 makes it possible to suppress the increase in the pattern widths of the board patterns 101 and 102 connecting electrical components inside the device. A connecting wire may be disposed on either of the board patterns 101 and 102. In this case, the increase in the pattern width of the board pattern on which the connecting wire is disposed can be suppressed.

In the power conversion device 1 according to Embodiment 1, the printed circuit board 2 is contained inside the housing 31. Either on a different surface or a different layer of the printed circuit board 2, in a board thickness direction of the board, from a surface of the printed circuit board 2 on which the board pattern 101 is formed, the board patterns 301 and 302 electrically connected to the housing 31 are provided. The board patterns 301 and 302 are arranged at positions where the board patterns 301 and 302 completely or partially overlap the points of connection between the board patterns 101 and 102 and the connecting wires 401 and 402, respectively, when viewed from the upper surface of the printed circuit board 2. Because the power conversion device has this configuration, the generation of heat in the board patterns 101 and 102 is propagated from the above-mentioned points of connection, via the printed circuit board 2 and the board patterns 301 and 302, to the housing 31. As a result, the power conversion device 1 can suppress the generation of heat in the board patterns 101 and 102 as compared with the configuration without the board patterns 301 and 302.

In the power conversion device 1 according to Embodiment 1, the connecting wires 401 and 402 are surface-mounted on the upper surfaces of the board patterns 101 and 102. As a result, the power conversion device 1 makes it possible to mount the connecting wires 401 and 402 through the surface mounting process commonly performed on other surface mount components, and to reduce the mounting cost of the components.

In the power conversion device 1 according to Embodiment 1, the connecting wires 401 and 402 are connected to the upper surfaces of the board patterns 101 and 102 respectively in the state where the portion between one end and the other end of each of the connecting wires 401 and 402 is spaced from a surface of the printed circuit board 2. Further, the connecting wires 401 and 402 are electrically connected in parallel to the board patterns 101 and 102, respectively. As a result, the effects of suppressing the generation of heat in the board patterns 101 and 102, the effects being provided by the connecting wires 401 and 402, can be enhanced.

In the power conversion device 1 according to Embodiment 1, the printed circuit board 2 is fastened, via the board patterns 301 and 302, to the housing 31 by the screws 32. Because the thermal resistances between the board patterns 301 and 302 and the housing 31 are reduced, it is possible to enhance the effects of suppressing the generation of heat in the board patterns 101 and 102.

In the power conversion device 1 according to Embodiment 1, the level of each of the connecting wires 401 and 402 from a surface of the printed circuit board 2 is lower than that of the current transformer 4 which is an electrical component. As a result, even in the case where the connecting wires 401 and 402 are mounted on the board patterns 101 and 102, the size in the level direction of the printed circuit board 2 can be made to fall within a range up to the level of the current transformer 4, and a downsizing of the power conversion device 1 can be achieved.

In the power conversion device 1 according to Embodiment 1, the current transformer 4 is an insulated type current sensor having the input terminals 32a and 32c and the output terminals 32b and 32d. The connecting wires 401 and 402 are arranged in parallel with an imaginary line X passing through the input terminal 32a and the output terminal 32b of the current transformer 4. As a result, because the board patterns 101 and 102 whose pattern widths are successfully decreased because of the connecting wires 401 and 402 are arranged in the vicinity of the current transformer 4, the wiring area on the upper surface of the printed circuit board 2 can be used effectively.

In the power conversion device 1 according to Embodiment 1, at least one of the fuse 3 and the current transformer 4 is a surface mount component to be surface-mounted on the printed circuit board 2. As a result, the fuse 3 or the current transformer 4 can be mounted through the surface mounting process commonly performed on other surface mount components, and the mounting cost of the components can be reduced.

### Embodiment 2

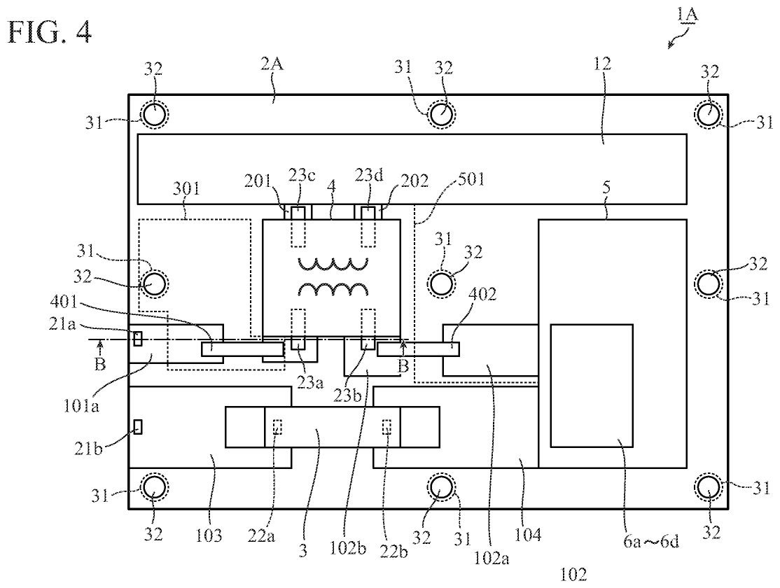

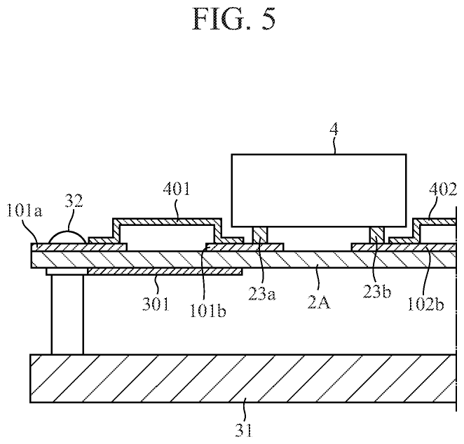

FIG. 4 is a top view showing a power conversion device 1A according to Embodiment 2. In FIG. 4, a printed circuit board 2A is a two-layer board. Although the printed circuit board 2A is a two-layer board which makes it possible to mount components on upper and lower surfaces thereof, this embodiment is not limited to this example, and the printed circuit board may be a multilayer board having three or more layers. FIG. is a partial cross-sectional arrow view showing a cross section of the power conversion device 1A, taken along the B-B line of FIG. 4. In FIG. 5, a control unit 12 is not shown for the sake of simplicity of illustration. Further, in FIGS. 4 and 5, the same components as those shown in FIGS. 2 and 3 are denoted by the same reference signs, and an explanation of the components will be omitted.

On the upper surface of the printed circuit board 2A, an input power supply terminal 21a on a positive side and an input power supply terminal 21b on a negative side are arranged, and a fuse 3, a current transformer 4, a power conversion circuit 5 and the control unit 12 are mounted. The input power supply terminals 21a and 21b are connected to an input power supply 100A shown in FIG. 1. The power conversion circuit 5 has semiconductor switching elements 6a to 6d. As shown in FIG. 5, the printed circuit board 2A is contained inside a housing 31 and is fastened to the housing 31 using screws 32.

Board patterns 101a, 101b, 102a, 102b, 103, 104, 201, 202, 301 and 501 are conductor patterns formed on the surfaces of the printed circuit board 2A. The board patterns 101a, 101b, 102a, 102b, 103, 104, 201 and 202 are formed on the upper surface of the printed circuit board 2A. The board patterns 301 and 501 are formed on the lower surface of the printed circuit board 2A, as shown by broken lines in FIG. 4.

In a case where the printed circuit board 2A is a multilayer board, and the board patterns 101a, 101b, 102a, 102b, 103, 104, 201 and 202 are formed in one layer in a laminating direction of the printed circuit board 2A, the board patterns 301 and 501 should just be formed in a layer under or above the layer in which the board patterns 101a, 101b, 102a, 102b, 103, 104, 201 and 202 are formed. More specifically, the board patterns 301 and 501 are formed either on a different surface or a different layer of the printed circuit board 2A, in a board thickness direction of the board, from a surface of the printed circuit board 2A on which the board pattern 101a is formed.

Each of the board patterns 101a and 101b is a first board pattern having a band shape, and the board patterns are arranged on the upper surface of the printed circuit board 2A with a spacing from each other along an imaginary line passing through an input terminal 23a and an output terminal 23b of the current transformer 4. At one end of the board pattern 101a the input power supply terminal 21a is provided, and the one end of the board pattern 101a is disposed in an end portion of the printed circuit board 2A. To the input power supply terminal 21a, a positive input voltage from the input power supply 100A shown in FIG. 1 is applied. Further, the board pattern 301 is a second board pattern formed on the lower surface of the printed circuit board 2A. A part of the board pattern 301 is disposed below a connecting wire 401 when viewed from the upper surface of the printed circuit board 2A, as shown in FIG. 4.

In the case where the printed circuit board 2A is a multilayer board, the board pattern 301 is disposed, in the layer in which the board pattern 301 is formed, at a position where the board pattern 301 overlaps the connecting wire 401 when viewed from the upper surface of the printed circuit board 2A.

Each of the board patterns 102a and 102b is a fourth board pattern having a band shape, and the board patterns are arranged on the upper surface of the printed circuit board 2A with a spacing from each other along the imaginary line passing through the input terminal 23a and the output terminal 23b of the current transformer 4. In addition, on the printed circuit board 2A the board pattern 102b is disposed with a spacing from the board pattern 101b. An end of the board pattern 102a is connected to the power conversion circuit 5. Further, a board pattern 302 is not disposed in the power conversion device 1A. The shapes of the board patterns 101a, 101b, 102a, 102b, 103 and 104 are not limited to band shapes, and may be other shapes.

The board pattern 501 formed on the lower surface of the printed circuit board 2A is a sixth board pattern which connects between the power conversion circuit 5 and the control unit 12, and which is formed below a connecting wire 402 when viewed from the upper surface of the printed circuit board 2A. The board pattern 501 is formed on the lower surface in such a way as to cross the connecting wire 402 placed on the upper surface of the printed circuit board 2A. Although the board pattern 501 formed below the connecting wire 402 is shown in FIG. 4, a board pattern may be formed on the lower surface of the printed circuit board 2A in such a way as to cross the connecting wire 401 placed on the upper surface of the printed circuit board 2A. This board pattern is a third board pattern of a conductor formed either on a different surface or a different layer of the printed circuit board 2A, in a board thickness direction of the board, from a surface of the printed circuit board 2A on which the first board patterns 101a and 101b are formed.

The connecting wire 401 is a first connecting wire which connects an end portion of an upper surface of the board pattern 101a and an end portion of an upper surface of the board pattern 101b. The connecting wire 402 is a second connecting wire which connects an end portion of an upper surface of the board pattern 102a and an end portion of an upper surface of the board pattern 102b. Each of the connecting wires 401 and 402 is formed of a conductor such as copper or aluminum.

A wire connecting the input terminal 23a of the current transformer 4 and the input power supply 100A includes the board patterns 101a and 101b and the connecting wire 401 connected to each of the upper surfaces of the board patterns 101a and 101b. Further, a wire connecting the power conversion circuit and the output terminal 23b of the current transformer 4 includes the board patterns 102a and 102b and the connecting wire 402 connected to each of the upper surfaces of the board patterns 102a and 102b. For example, a set of the board patterns 101a and 101b and the connecting wire 401 connected to the upper surfaces of these board patterns 101a and 101b is a wire connecting the input power supply terminal 21a connected to the input power supply 100A and the input terminal 23a of the current transformer 4 in series, a set of the board patterns 102a and 102b and the connecting wire 402 connected to these board patterns 102a and 102b is a wire connecting the output terminal 23b of the current transformer 4 and the power conversion circuit 5 in series, as shown in FIG. 4.

The connecting wires 401 and 402 are arranged in parallel with the imaginary line passing through the input terminal 23a and the output terminal 23b of the current transformer 4. As a result, because the board patterns 101a, 101b, 102a and 102b whose pattern widths are successfully decreased using the connecting wires 401 and 402 are arranged in the vicinity of the current transformer 4, the wiring area on the upper surface of the printed circuit board 2A can be used effectively.

For example, the thicknesses of the board patterns 101a, 101b, 102a and 102b are within a range from several micrometers to several tens of micrometers, and each of the connecting wires 401 and 402 is formed in such a way as to have a thickness of several millimeters. More specifically, by setting the connecting wires 401 and 402 as conductor wires which are sufficiently thicker than the board patterns 101a, 101b, 102a and 102b, it is possible to enhance the effect of suppressing the generation of heat in the board patterns 101a, 101b, 102a and 102b. As a result, because the generation of heat in the board patterns is suppressed without having to increase the pattern widths of the board patterns, the power conversion device 1A makes it possible to suppress the increase in the pattern widths of the board patterns connecting the electrical components inside the device.

Because the connecting wires 401 and 402 serve as heat generation suppression members for the board patterns 101a, 101b, 102a and 102b, it is not necessary to increase the surface areas of the board patterns 101a, 101b, 102a and 102b for the purpose of heat dissipation. Therefore, the generation of heat in the board patterns 101a, 101b, 102a and 102b can be suppressed even though the pattern widths of the board patterns are made to be narrow compared with those of the board patterns 103 and 104, as shown in FIG. 4. As a result, the power conversion device 1A makes it possible to downsize the printed circuit board 2A.

One end of the connecting wire 401 is connected to the upper surface of the board pattern 101a and the other end of the connecting wire 401 is connected to the upper surface of the board pattern 101b in a state where a spacing is provided between the portion between the one end and the other end of the connecting wire 401, and a surface of the printed circuit board 2, as shown in FIG. 4. Similarly, one end of the connecting wire 402 is connected to the upper surface of the board pattern 102a and the other end of the connecting wire 402 is connected to the upper surface of the board pattern 102b in a state where a spacing is provided between the portion between the one end and the other end of the connecting wire 402, and the surface of the printed circuit board 2A. For example, the connecting wire 401 is electrically connected in series to the board patterns 101a and 101b, and the connecting wire 402 is electrically connected in series to the board patterns 102a and 102b.

Further, because no board pattern 302 is disposed in the power conversion device 1A, as shown in FIG. 4, the board patterns 102a and 102b are formed with pattern widths which are determined in consideration of only the amount of generated heat propagating from the current transformer 4 via the board pattern 102b. In this case, in conventional power conversion devices which do not use the connecting wires 401 and 402, it is difficult to establish the thermal feasibility of the printed circuit board 2A and the current transformer 4. In contrast with this, in the power conversion device 1A, the connecting wire 402 is disposed in the vicinity of the current transformer 4, and the board patterns 102a and 102b are connected in series by the connecting wire 402.

Because the cross-sectional area of the connecting wire 402 is large compared with those of the board patterns 102a and 102b, and the amount of heat generated in the connecting wire 402 is small compared with those in the board patterns 102a and 102b, the amount of heat applied from the connecting wire 402 to the current transformer 4 is also small. As a result, the power conversion device 1A makes it possible to suppress the generation of heat therein even though each of the pattern widths of the board patterns 102a and 102b is made to be narrow compared with those in conventional power conversion devices which do not use the connecting wires 401 and 402.

The board pattern 301 is a conductor pattern formed on the lower surface of the printed circuit board 2A, and is electrically connected to the housing 31. The board pattern 301 is disposed at a position where the board pattern 301 completely or partially overlaps points of connection between the board patterns 101a and 101b and the connecting wire 401 when viewed from the upper surface of the printed circuit board 2A, as shown in FIG. 4. As a result, a heat path through which the heat from the board patterns 101a and 101b is propagated from the above-mentioned points of connection, via the printed circuit board 2A and the board pattern 301, to the housing 31 is formed. Because the generation of heat in the board patterns 101a and 101b is suppressed through this heat path, it is possible to suppress the generation of heat in the board patterns 101a and 101b even though the pattern widths of the board patterns 101a and 101b are made to be narrow compared with the board patterns 102a and 102b not having the board pattern 301.

As shown in FIG. 4, the connecting wire 402 and the board pattern 501 overlap each other when the printed circuit board 2A is viewed from the upper surface of the board. The board pattern 501 is disposed on the lower surface of the printed circuit board 2A, like the board pattern 301, and electrically connects between the power conversion circuit 5 and the control unit 12. The board pattern 501 is, for example, a signal line for driving the semiconductor switching elements 6a to 6d included in the power conversion circuit 5.

In general, it is necessary to dispose a wire electrically connecting the power conversion circuit 5 and the control unit 12 in such a way that the wire does not overlap any other board pattern when viewed from the upper surface of the printed circuit board 2A, for the purpose of improving the noise resistance. In conventional power conversion devices, such wires are bypassed and arranged in such a way as not to overlap board patterns, and a printed circuit board 2A is upsized.

In contrast with this, because in the power conversion device 1A the connecting wire 402 connects the board pattern 102a and the board pattern 102b in series, the pattern widths of the board patterns 102a and 102b can be decreased. Therefore, a wiring area is provided between the board pattern 102a and the board pattern 104, as shown in FIG. 4. As a result, the board pattern 501 does not overlap any other board pattern, but overlaps only the connecting wire 402 when viewed from the upper surface of the printed circuit board 2A, and therefore a downsizing of the power conversion device 1A can be achieved.

As mentioned above, in the power conversion device 1A according to Embodiment 2, the connecting wire 401 connects the board pattern 101a and the board pattern 101b in series. The connecting wire 402 connects the board pattern 102a and the board pattern 102b in series. As a result, because the connecting wires 401 and 402 which are sufficiently thicker than the board patterns 101a, 101b, 102a and 102b function as heat generation suppression members, and the generation of heat in these board patterns is suppressed without having to increase their pattern widths, the power conversion device 1A makes it possible to suppress the increase in the wire widths of the wires connecting the electrical components inside the device.

### Embodiment 3

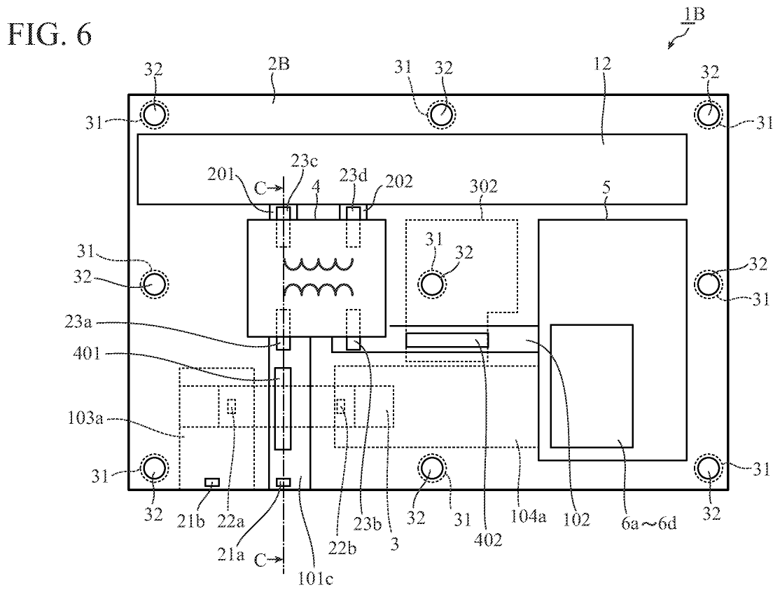

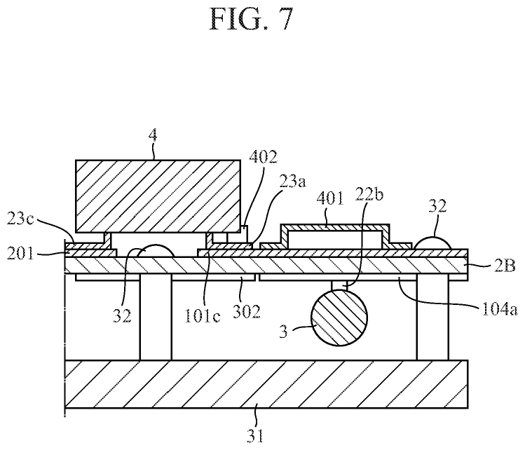

FIG. 6 is a top view showing a power conversion device 1B according to Embodiment 3. In FIG. 6, a printed circuit board 2B is a two-layer board. Although the printed circuit board 2B is a two-layer board which makes it possible to mount components on upper and lower surfaces thereof, this embodiment is not limited to this example, and the printed circuit board may be a multilayer board having three or more layers. FIG. 7 is a partial cross-sectional arrow view showing a cross section of the power conversion device 1B, taken along the C-C line of FIG. 6. In FIG. 7, a power conversion circuit 5 and a control unit 12 is not shown for the sake of simplicity of illustration. Further, in FIGS. 6 and 7, the same components as those shown in FIGS. 2 and 3 are denoted by the same reference signs, and an explanation of the components will be omitted.

On the upper surface of the printed circuit board 2B, an input power supply terminal 21a on a positive side and an input power supply terminal 21b on a negative side are arranged, and a fuse 3, a current transformer 4, the power conversion circuit and the control unit 12 are mounted. The input power supply terminals 21a and 21b are connected to an input power supply 100A shown in FIG. 1. The power conversion circuit 5 has semiconductor switching elements 6a to 6d. As shown in FIG. 6, the printed circuit board 2B is contained inside a housing 31 and is fastened to the housing 31 using screws 32. The fuse 3 is disposed on the lower surface of the printed circuit board 2B, i.e., a surface opposite to a surface on which connecting wires 401 and 402 are arranged. As a result, a mount area on the upper surface of the printed circuit board 2B can be ensured.

Board patterns 101c, 102, 103a, 104a, 201, 202 and 302 are conductor patterns formed on the surfaces of the printed circuit board 2B. Here, the board patterns 101c, 102, 201 and 202 are formed on the upper surface of the printed circuit board 2B. The board patterns 103a, 104a and 302 are formed on the lower surface of the printed circuit board 2B, as shown by a broken line in FIG. 6.

In a case where the printed circuit board 2B is a multilayer board, and the board patterns 101c, 102, 201 and 202 are formed either on one surface or in one layer of the printed circuit board 2B in a bord thickness direction of the board, the board patterns 103a, 104a and 302 should just be formed either on a different surface or a in a different layer from the surface or the layer where the board patterns 101c, 102, 201 and 202 are formed.

The board pattern 101c is a first board pattern having a band shape, and is disposed along an imaginary line passing through a primary input terminal 23a and a secondary input terminal 23c of the current transformer 4 on the upper surface of the printed circuit board 2B. One end of the board pattern 101c is one at which the input power supply terminal 21a is disposed, and is disposed in an end portion of the printed circuit board 2B. To the input power supply terminal 21a, a positive input voltage from the input power supply 100A shown in FIG. 1 is applied.

The board pattern 102 is a fourth board pattern having a band shape, and, on the upper surface of the printed circuit board 2B, a line which is an extension of an imaginary center line of the board pattern 102 crosses the board pattern 101c at right angles and the board pattern 102 is disposed with a spacing from the board pattern 101c. A first end of the board pattern 102, the first end being opposite to a second end of the board pattern 102 and the second end facing the board pattern 101c, is connected to the power conversion circuit 5. The board pattern 302 is a fifth board pattern formed on the lower surface of the printed circuit board 2B. A part of the board pattern 302 is disposed below the connecting wire 402 when viewed from the upper surface of the printed circuit board 2B, as shown in FIGS. 6 and 7.

In the case where the printed circuit board 2B is a multilayer board, in the layer in which the board pattern 302 is formed, the board pattern 302 is disposed at a position where the board pattern 302 overlaps the connecting wire 402 when viewed from the upper surface of the printed circuit board 2B.

The board pattern 103a has a band shape wider than the board pattern 101c, and an end of the board pattern 103a is disposed in an end portion of the printed circuit board 2B. At the part of the board pattern 103a disposed in the end portion of the printed circuit board 2B, the negative input power supply terminal 21b is disposed. To the input power supply terminal 21b, a negative input voltage from the input power supply 100A shown in FIG. 1 is applied. The board pattern 104a has a band shape of the same width as the board pattern 103a, and is disposed with a spacing from the board pattern 103a. A first end of the board pattern 104a, the first end being opposite to a second end of the board pattern 104a and the second end facing the board pattern 103a, is connected to the power conversion circuit 5. The shapes of the board patterns 101c, 102, 103a and 104a are not limited to band shapes, and may be other shapes.

The connecting wire 401 is a first connecting wire connected to an upper surface of the board pattern 101c. The connecting wire 402 is a second connecting wire connected to an upper surface of the board pattern 102. Each of the connecting wires 401 and 402 is formed of a conductor such as copper or aluminum.

For example, each of the thicknesses of the board patterns 101c and 102 is within a range from several micrometers to several tens of micrometers, and each of the connecting wires 401 and 402 is formed in such a way as to have a thickness of several millimeters. More specifically, by setting the connecting wires 401 and 402 as conductor wires which are sufficiently thicker than the board patterns 101c and 102, it is possible to enhance the effect of suppressing the generation of heat in the board patterns 101c and 102. As a result, the power conversion device 1B makes it possible to suppress the generation of heat in the board patterns connecting the electrical components inside the device.

Because the connecting wires 401 and 402 serve as heat generation suppression members for the board patterns 101c and 102, it is not necessary to increase the surface areas of the board patterns 101c and 102 for the purpose of heat dissipation. Therefore, the pattern widths of the board patterns 101c and 102 can be made to be narrow compared with those of the board patterns 103 and 104, as shown in FIG. 6. As a result, the power conversion device 1B makes it possible to downsize the printed circuit board 2B.

The power conversion device 1B does not include a board pattern 301, but includes the board pattern 302 on the printed circuit board 2B. As shown in FIG. 6, the board pattern 302 is disposed at a position where the board pattern 302 completely or partially overlaps a point of connection between the board pattern 102 and the connecting wire 402 when viewed from the upper surface of printed circuit board 2B. As a result, a heat path through which the heat from the board pattern 102 is propagated from the above-mentioned point of connection, via the printed circuit board 2B and the board pattern 302, to the housing 31 is formed. Because the generation of heat in the board pattern 102 is suppressed through this heat path, it is possible to suppress the generation of heat in the board pattern 102 even though the pattern width of the board pattern 102 is made to be narrow compared with the board pattern 101c not having the board pattern 302.

The fuse 3 is mounted below the board pattern 101c and the connecting wire 401 when viewed from the upper surface of the printed circuit board 2B. For example, the board pattern 101c and the connecting wire 401 are arranged between an input terminal 22a and an output terminal 22b of the fuse 3, as shown in FIG. 6. In a case where the fuse 3 is a small-sized element, the distance between the input terminal 22a and the output terminal 22b is also short. In this case, in order to route the board patterns on the printed circuit board 2B while ensuring an insulation distance between the input power supply terminal 21a and the input power supply terminal 21b, it is necessary to decrease the pattern width of the board pattern 101c, and therefore the heat dissipation characteristic of the board pattern 101c degrades. In conventional power conversion devices, in a case of preventing such degradation of the heat dissipation characteristic of a board pattern 101c, the board pattern 101c is supposed to be formed in such away as to bypass a board pattern 103a. Therefore, a conventional printed circuit board 2B is upsized.

In contrast with this, because in the power conversion device 1B, the generation of heat in the board pattern 101c is suppressed by means of the connection of the connecting wire 401 to the upper surface of the board pattern 101c, the pattern width of the board pattern 101c can be decreased. As a result, the board pattern 101c can be disposed between the board pattern 103a and the board pattern 104, and the printed circuit board 2B can be downsized.

As mentioned above, in the power conversion device 1B according to Embodiment 3, the fuse 3 is disposed on the lower surface of the printed circuit board 2B. As a result, a mount area on the upper surface of the printed circuit board 2B can be ensured. On the printed circuit board 2B, the board pattern 302 is disposed at a position where the board pattern 302 completely or partially overlaps the point of connection between the board pattern 102 and the connecting wire 402 when viewed from the upper surface of the printed circuit board 2B. A heat path through which the heat from the board pattern 102 is propagated from the above-mentioned point of connection, via the printed circuit board 2B and the board pattern 302, to the housing 31 is formed. Because the generation of heat in the board pattern 102 is suppressed via this heat path, it is possible to suppress the generation of heat in the board pattern 102 even though the pattern width of the board pattern 102 is made to be narrow compared with that of the board pattern 101c not having the board pattern 302.

It is to be understood that a combination of embodiments can be made, various changes can be made in any component in each of the embodiments, or any component in each of the embodiments can be omitted.

### REFERENCE SIGNS LIST

1, 1A, 1B power conversion device, 2, 2A, 2B printed circuit board, 3 fuse, 4 current transformer, 5 power conversion circuit, 6a to 6d semiconductor switching element, 7 transformer, 8a, 8b semiconductor element, 9 smoothing reactor, smoothing capacitor, 11a input voltage detection circuit, 11b output voltage detection circuit, 12 control unit, 13 current to voltage conversion circuit, 21a, 21b input power supply terminal, 22a, 23a, 23c input terminal, 22b, 23b, 23d output terminal, 31 housing, 32 screw, 100A input power supply, 100B external load, 100C output power supply, 101, 101a to 101c, 102, 102a, 102b, 103, 103a, 104, 104a, 201, 202, 301, 302, 501 board pattern, and 401, 402 connecting wire.

What is claimed is:

1. A power conversion device comprising:
a power conversion circuit having multiple semiconductor switching elements;
an electrical component connected to an input power supply and the power conversion circuit;
a printed circuit board for which the electrical component is provided;
a board pattern which is a conductor pattern formed on an upper surface of the printed circuit board; and
a connecting wire formed of a conductor,
wherein at least one of a wire connecting the electrical component and the input power supply and a wire connecting the electrical component and the power conversion circuit includes the board pattern and the connecting wire connected to an upper surface of the board pattern.

2. The power conversion device according to claim 1, wherein the board pattern is a first board pattern formed on the upper surface of the printed circuit board, the connecting wire is a first connecting wire connected to an upper surface of the first board pattern, and the wire connecting the electrical component and the input power supply includes the first board pattern and the first connecting wire connected to the upper surface of the first board pattern.

3. The power conversion device according to claim 2, wherein the printed circuit board is contained inside a housing, and
wherein the power conversion device includes a second board pattern which is a conductor pattern formed either on a different surface or in a different layer of the printed circuit board, in a board thickness direction of the printed circuit board, from the upper surface of the printed circuit board on which the first board pattern is formed, and which is electrically connected to the housing, and
the second board pattern is disposed at a position where the second board pattern completely or partially overlaps a part of connection between the first board pattern and the first connecting wire when viewed from the upper surface of the printed circuit board.

4. The power conversion device according to claim 2, wherein the first connecting wire is connected in series to the first board pattern, and
wherein the power conversion device includes a third board pattern which is a conductor pattern formed either on a different surface or in a different layer of the printed circuit board, in a board thickness direction of the printed circuit board, from the upper surface of the printed circuit board on which the first board pattern is formed, and the third board pattern is formed below the first connecting wire when viewed from the upper surface of the printed circuit board.

5. The power conversion device according to claim 3, wherein the printed circuit board is fastened, via the second board pattern, to the housing by screws.

6. The power conversion device according to claim 1, wherein the board pattern is a fourth board pattern formed on the upper surface of the printed circuit board, the connecting wire is a second connecting wire formed of a conductor, and the wire connecting the power conversion circuit and the electrical component includes the fourth board pattern and the second connecting wire connected to an upper surface of the fourth board pattern.

7. The power conversion device according to claim 6, wherein the printed circuit board is contained inside a housing, and
wherein the power conversion device includes a fifth board pattern which is a conductor pattern formed either on a different surface or in a different layer of the printed circuit board, in a board thickness direction of the printed circuit board, from the upper surface of the printed circuit board on which the fourth board pattern is formed, and which is electrically connected to the housing, and the fifth board pattern is formed below the second connecting wire when the printed circuit board is viewed from the upper surface.

8. The power conversion device according to claim 6, wherein the connecting wire is connected in series to the board pattern and the printed circuit board is contained inside a housing, and
wherein the power conversion device includes a sixth board pattern which is a conductor pattern formed either on a different surface or a different layer of the printed circuit board, in a board thickness direction of the printed circuit board, from the upper surface of the printed circuit board on which the fourth board pattern is formed, and the sixth board pattern is formed below the second connecting wire when viewed from the upper surface of the printed circuit board.

9. The power conversion device according to claim 7, wherein the printed circuit board is fastened, via the fifth board pattern, to the housing by screws.

10. The power conversion device according to claim 1, wherein the connecting wire is surface-mounted on the upper surface of the board pattern.

11. The power conversion device according to claim 1, wherein the connecting wire is connected to the upper surface of the board pattern in a state where a portion between one end and another end of the connecting wire is spaced from the upper surface of the printed circuit board.

12. The power conversion device according to claim 1, wherein the connecting wire is connected in parallel to the board pattern.

13. The power conversion device according to claim 1, wherein the connecting wire is connected in series to the board pattern.

14. The power conversion device according to claim 1, wherein a level of the connecting wire from the upper surface of the printed circuit board is lower than that of the electrical component.

15. The power conversion device according to claim 1, wherein the electrical component is an insulated type current sensor.

16. The power conversion device according to claim 15, wherein the connecting wire is disposed in parallel with an imaginary line passing through an input terminal and an output terminal of the current sensor.

17. The power conversion device according to claim 15, wherein the power conversion device includes a fuse connected to the input power supply and the power conversion circuit, the fuse is disposed on a surface of the printed circuit board, the surface being opposite to the upper surface of the printed circuit board on which the connecting wire is disposed, and the board pattern and the connecting wire are arranged between an input terminal and an output terminal of the fuse.

18. The power conversion device according to claim 1, wherein the electrical component is at least one of an insulated type current sensor and a fuse, and at least one of the current sensor and the fuse is a surface mount component to be surface-mounted on the printed circuit board.
